(19) United States
(12) Patent Application Publication
(10) Pub. No.: US 2014/0072294 A1
(43) Pub. Date: Mar. 13, 2014

(54) DIAL SWITCH

(71) Applicant: SONY CORPORATION, Minato-ku (JP)

(72) Inventor: Kenji HIMENO, Kanagawa (JP)

(73) Assignee: SONY CORPORATION, Minato-ku (JP)

(21) Appl. No.: 13/965,680

(22) Filed: Aug. 13, 2013

(30) Foreign Application Priority Data
Sep. 7, 2012 (JP) 2012-197614

(51) Int. Cl. H03K 17/78; G03B 17/00

(52) U.S. Cl. CPC H03K 17/78; G03B 17/00
USPC 396/543

(57) ABSTRACT

There is provided a dial switch including a first dial freely rotatable in a rotational direction throughout an entire circumference of the first dial, a second dial freely rotatable about the same rotational center as the first dial in the rotational direction throughout the entire circumference, and a non-contact sensor that detects a rotation position and a rotational direction of at least one of the first dial and the second dial.

### BACKGROUND

The present disclosure relates to a dial switch, and more particularly, to a dial switch used for selection and setting of various conditions or the like of an electronic instrument.

In an electronic instrument, for example, in an imaging apparatus, a dial switch configured to switch a photographing condition (a photographing mode) and set parameters or the like is installed. Functionality of the imaging apparatus increases each year, and thus a compact and slim structure and saving in space are necessary. For this reason, overlapping of dial switches in a vertical two-stage manner in order to integrate functions such as switching of various conditions, setting of parameters, and so on, to save space is considered.

In Japanese Patent No. 4471817, a multi-functional electronic part in which two kinds of rotary electronic parts and a push type electronic part are integrated to provide a compact and slim structure is disclosed. In Japanese Patent No. 4471817, a shaft support section of an attachment member between a first rotary member and a second rotary member pivotally support a shaft of the second rotary member, a pressing section of the push button knob fastener passes through the shaft support section, and electrical function sections of the push button knob fastener are integrated at a lower side of the attachment member, providing a slim structure of the multi-functional electronic part.

Japanese Unexamined Patent Application Publication No. H09-043705 discloses a dial switch including first and second dial operation members, an exterior member having an opened hole and used to restrict a rotation amount of any one of the dial operation members, and a rotation support member configured to support the two dial operation members and having a flange including a plurality of fixing sections fixed to the exterior member. Then, in Japanese Unexamined Patent Application Publication No. H09-043705, a rotation support unit having insufficient strength due to its insufficient thickness at a place at which rotation of the two-stage dial is supported, in consideration of a space, is constituted by a separate member from an upper lid formed of a material having a low strength, and formed of a separate material having a higher static pressure strength than that of the upper lid. Accordingly, in Japanese Unexamined Patent Application Publication No. H09-043705, rotation support strength of a dial and endurance strength of a lock configured to restrict rotation of the dial are enhanced without changing a material of the upper lid, and thus reliability and durability of products are improved.

### SUMMARY

When the two-stage dial switch in which dials overlap in a vertical two-stage manner, a rotation detection mechanism of the dials is complicated in structure and increased in size. In particular, when the dial of a lower stage is rotated throughout the entire circumference, a structure of the two-stage dial switch is not increased in size, and the rotation detection function is hardly installed in the two-stage dial switch.

Even in Japanese Patent No. 4471817 and Japanese Unexamined Patent Application Publication No. H09-043705, while a compact structure of the dial switch is attempted, its structure is complicated and the number of used parts is also large. Further, in Japanese Patent No. 4471817 and Japanese Unexamined Patent Application Publication No. H09-043705, the dial of the lower stage is not rotated throughout the entire circumference.

Accordingly, it is desirable to provide a dial switch capable of freely rotating vertically overlapping dials in two stages in a rotational direction through the entire circumference, and realizing a compact and slim structure thereof.

According to an embodiment of the present disclosure, there is provided a dial switch including a first dial freely rotatable in a rotational direction throughout an entire circumference of the first dial, a second dial freely rotatable about the same rotational center as the first dial in the rotational direction throughout the entire circumference, and a non-contact sensor that detects a rotation position and a rotational direction of at least one of the first dial and the second dial.

According to embodiments of the present disclosure, it is possible to provide the dial switch capable of rotating the vertically overlapping dials in two stages in a rotational direction through the entire circumference, and realizing a compact and slim structure thereof.

### BRIEF DESCRIPTION OF THE DRAWINGS

FIG. 1 is a perspective view showing an example in which a dial switch according to an embodiment of the present disclosure is assembled to an apparatus main body of an electronic instrument;

FIG. 2 is a perspective view showing a configuration example of the dial switch according to an embodiment of the present disclosure;

FIG. 3 is an exploded perspective view showing the configuration example of the dial switch according to an embodiment of the present disclosure; and

FIG. 4 is a cross-sectional view taken along line A-A shown in FIG. 2 of the dial switch according to an embodiment of the present disclosure.

### DETAILED DESCRIPTION OF THE EMBODIMENTS

An Embodiment described in below is an appropriate specific example of the present disclosure, and appropriate and various technical limitations are applied. However, in the following description, the scope of the present disclosure is not limited to the embodiment unless the present disclosure describes specific limitations.

In addition, the present disclosure will be described in a sequence as follows.

```
<1. Embodiment of the present disclosure>
  [Summary of dial switch]
  [Configuration of dial switch]
  [Configuration members of dial switch]
  [Operation of dial switch]
<2. Variant>
```

### 1. Embodiment of the Present Disclosure

[Summary of Dial Switch]

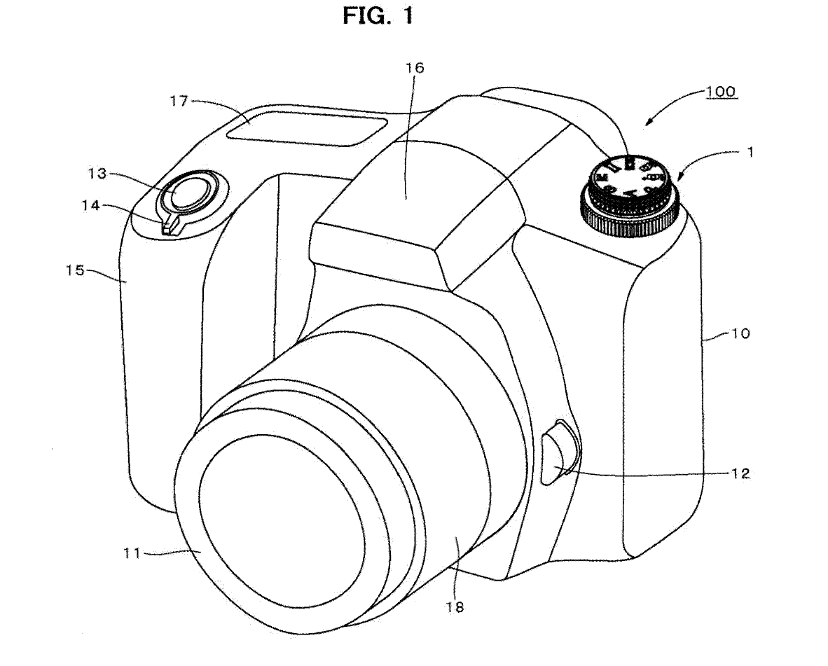

First, an electronic instrument to which a dial switch according to an embodiment of the present disclosure is applicable will be described. FIG. 1 shows an example in which a dial switch according to an embodiment of the present disclosure is assembled to an apparatus main body of an electronic instrument. An imaging apparatus 100 is an example of the electronic instrument to which a dial switch 1 according to the embodiment of the present disclosure is applicable. The imaging apparatus 100 is configured as, for example, a digital one eye camera in which a lens is exchangeable with another one.

The imaging apparatus 100 has a camera main body section 10 and a lens unit 11. The lens unit 11 is configured to be detachable with respect to the camera main body section 10. Then, the lens unit 11 selected from a zoom lens, a telephoto lens of a single focus lens, a macro lens, and so on, is appropriately attached to the camera main body section 10 to be used. Meanwhile, when a lens exchange button 12 adjacent to the lens unit 11 is pressed, the lens unit 11 is removed from the camera main body section 10.

The dial switch 1, a shutter button 13 and a zoom lever 14 are installed at the camera main body section 10. A grip section 15 may be formed in the vicinity of the shutter button 13. The inside of the formed grip section 15 is used as a space configured to provide a battery chamber in which a battery, for example, a lithium ion secondary battery, is accommodated as a power supply of the imaging apparatus 100, and a memory card slot in which a recording medium configured to store image data of a captured image or the like, for example, a memory card, is removably accommodated.

A built-in flash 16 may be installed at the camera main body section 10. Instead of the built-in flash 16, a connecting terminal or the like configured to attach an external flash may be installed. In FIG. 1, a pop-up type built-in flash 16 is illustrated as an example. A setting display section 17 may be installed at the camera main body section 10. For example, information such as a diaphragm (an F value) is displayed in the setting display section 17. Other information may be displayed on the setting display section 17.

The lens unit 11 has a lens group constituted by a plurality of lenses disposed in a substantially tubular barrel 18. The lens group is an optical system configured to form an image through light (a light image) from an object on a light receiving plane of a solid state imaging element (a photoelectric conversion element) (not shown) disposed in the camera main body section 10. In addition, the light formed as an image on the solid state imaging element is then photoelectrically converted into an electric signal, processed in an image processing processor (not shown) in the camera main body section 10, and recorded on a memory card as digital image data.

The lens group includes, for example, a focus lens configured to adjust focus, and a zoom lens configured to vary magnification. When the respective lenses are appropriately moved in an optical axis direction, the focus is adjusted and the magnification is varied. A focus adjustment ring may be installed at the barrel 18 of the lens unit 11. When the ring is rotated, the lens can move, and manual focus can be performed. Further, a ring that can be rotated to vary a zoom magnification through manual operation may be installed at a circumferential surface of the barrel 18 of the lens unit 11. The zoom lens may be moved by operating the above-mentioned zoom lever 14. The zoom lenses move in the optical axis direction according to a rotational direction and a rotation amount of the ring by a manual operation or an automatic operation, and the zoom magnification is set according to a position after movement.

The shutter button 13 is installed on an upper surface of the grip section 15. The shutter button 13 is configured as a switch that can allow, for example, two stages of pressed states including a “half pressed” state in which the shutter button 13 is not fully pressed but pressed halfway, and a “fully pressed” state in which the shutter button 13 is fully pressed. When the shutter button 13 is half pressed, a preparation operation for imaging an object is performed. As the preparation operation for imaging the object, a detection operation of detecting focus, setting an exposure control value, or the like, is illustrated as an example. In addition, when the shutter button 13 is released from the half pressed state, the preparation operation is terminated.

When the shutter button 13 is further pressed from the half pressed state into the fully pressed state, imaging processing such as exposure of an object image (a light image of the object) to the solid state imaging element (not shown), signal processing by an image processing processor (not shown), recording of imaging data to a recording medium, and so on, is performed. As described above, in the imaging apparatus 100, it is regarded that imaging preparation is instructed when the shutter button 13 is half pressed, and imaging is instructed when the shutter button 13 is fully pressed.

The dial switch 1 configured to set a photographing mode or the like is installed at a top surface (referred to also as a top surface warship section) of the camera main body section 10. Various operation members, not limited to the dial switch 1, may be disposed on the top surface of the camera main body section 10. Accordingly, the dial switch 1 according to an embodiment of the present disclosure in which functions are integrated and a compact structure is realized is advantageous in that a space limited to the top surface is effectively utilized. An outer circumferential surface of the vertical two-stage dial of the dial switch 1 is exposed throughout the entire circumference, and in particular, operation performance of the lower stage is improved and design performance is also good. Further, the dial switch 1 according to an embodiment of the present disclosure is characterized in that operation in the entire circumferential direction becomes possible.

The dial switch 1 has a substantially disc-shaped rotatable in a surface substantially parallel to the top surface of the camera main body section 10, and marks corresponding to the respective modes are attached to the top surface of the dial switch 1. A mode is selected by rotating the dial switch 1 such that the mark corresponding to the mode desired by a user matches a predetermined position.

As modes that can be set by the dial switch 1, an automatic mode or an automatic exposure (AE) control mode, an automatic focus (AF) control mode, a still image imaging mode of imaging a still image, a continuous imaging mode of performing continuous imaging, a play mode of playing an imaged still image or the like, and so on, are illustrated as an example. The dial switch 1 will be described in detail as follows.

In addition, in the imaging apparatus 100 shown in FIG. 1, in addition to the shown configurations, other configurations may be added, and some of the shown configurations may be removed. Places at which the respective configurations such as the dial switch 1, the shutter button 13, and so on, are disposed may be appropriately varied. For example, the top surface of the dial switch 1 may be disposed at any place, and further, the top surface may be disposed at a rear surface or the like.

[Configuration of Dial Switch]

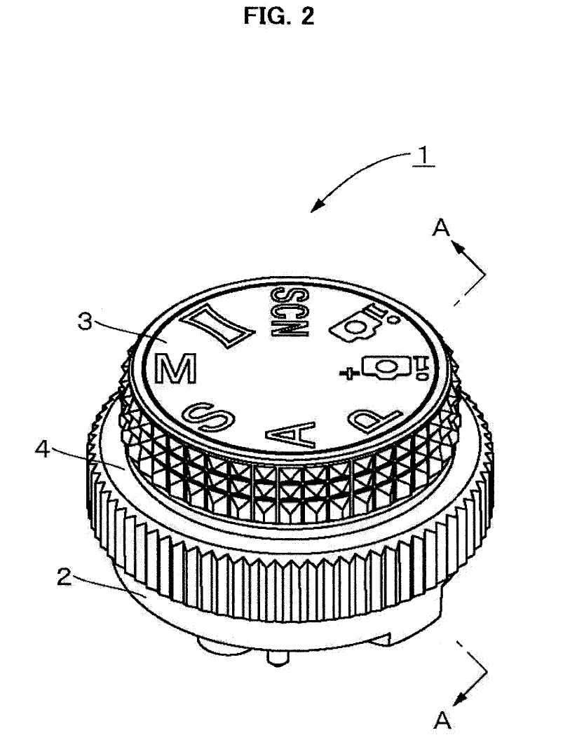

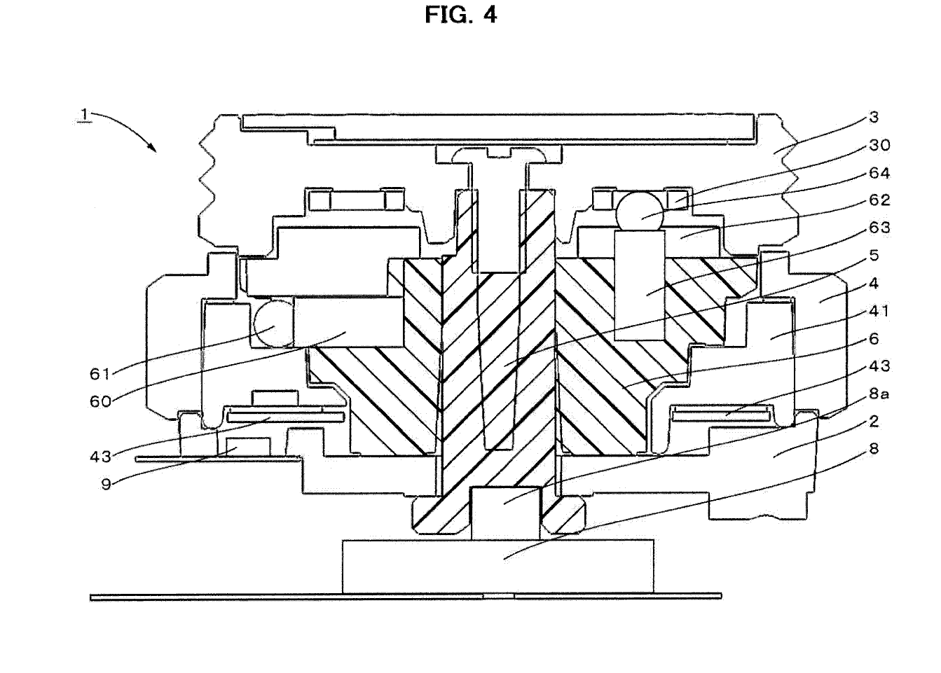

Next, a configuration of the dial switch according to an embodiment of the present disclosure will be described. FIG. 2 shows a configuration example of the dial switch according to an embodiment of the present disclosure. In addition, a cross-section taken along line A-A illustrated in FIG. 2 is shown in FIG. 4 and will be described below. In the following description, a first dial recited in the claims is referred to as a dial A, and “A” is added to configurations related to the dial A. Further, a second dial recited in the claims is referred to as a dial B, and “B” is added to configurations related to the dial B.

The dial switch 1 has a non-contact sensor (not shown), a dial A3, and a dial B4, attached to a base plate 2. The dial B4 is placed on the base plate 2, and the dial A3 overlaps the dial B4 to form a two-stage configuration of the dial switch 1.

The dial A3 is configured to be freely rotatable in the rotational direction throughout the entire circumference. Further, the dial B4 has the same rotational center as the dial A3, and is freely rotatable in the rotational direction throughout the entire circumference. The dial A3 and the dial B4 are rotated independently from each other. Here, “freely rotatable in the rotational direction” means that the dials can be rotated in both clockwise and counterclockwise directions when seen from the top surface of the dial switch 1. Further, “rotatable throughout the entire circumference” means that the dial can be rotated 360 degrees or more. The non-contact sensor (not shown) detects a rotation position and a rotational direction of at least one of the dial A3 and the dial B4.

The dial A3 of a first stage (an upper stage) is, for example, set to a mode dial, which is used as a mode (stage) change switch rotated throughout the entire circumference. Meanwhile, the dial B4 of a second stage (a lower stage) is, for example, set to an assist dial, which is a switch used to change the entire contents that can be controlled by the imaging apparatus 100 (see FIG. 1), such as a diaphragm, a shutter speed, ISO sensitivity, a menu, and so on, in steps. That is, the dial B4 is a parameter change dial. In addition, since a rotational direction, a rotation angle (a rotation position), and so on, of the dial B4, can be detected, like the dial A3, the dial B4 can also be used as a switch for changing a stage such as a mode or the like.

Marks corresponding to photographing modes are marked on the top surface of the dial switch 1 of FIG. 2. As an example, the photographing modes includes items of P (programmed auto), A (diaphragm first), S (shutter speed first), M (manual exposure), swing panorama, SCN (scene selection), selected auto and premium selected auto. The photographing modes of P, A, S and M are referred to as exposure modes. The exposure modes can selectively adjust a shutter speed and a diaphragm (an F value). Meanwhile, in the photographing modes of SCN, selected auto and premium selected auto, the camera sets the shutter speed and the diaphragm.

P (programmed auto): Auto photographing in which preference setting other than exposure (the shutter speed and the diaphragm) can be set. The camera sets the shutter speed and the diaphragm to provide appropriate exposure.

A (diaphragm first): Photographing is performed by varying a focused range or a shading condition of a background. The camera sets the shutter speed to provide appropriate exposure with respect to the adjusted diaphragm.

S (shutter speed first): Photographing is performed by adjusting the shutter speed and varying expression of a moving subject. The camera sets the diaphragm to provide appropriate exposure with respect to the adjusted shutter speed.

M (manual exposure): The diaphragm and the shutter speed are adjusted. The camera does not set the diaphragm and the shutter speed.

Swing panorama: Photographing is performed at a panoramic size.

SCN (scene selection): Photographing is performed at a mode appropriate for an object or an environment to be photographed.

Selected auto: The camera automatically determines a photographing circumstance (scene) to perform automatic photographing.

Premium selected auto: Continuous photographing is performed according to a recognized scene, and images are synthetically processed (superposition photographing). Accordingly, a higher resolution image is photographed.

In addition, the above-mentioned photographing modes are exemplary examples, and other items may be added.

[Configuration Members of Dial Switch]

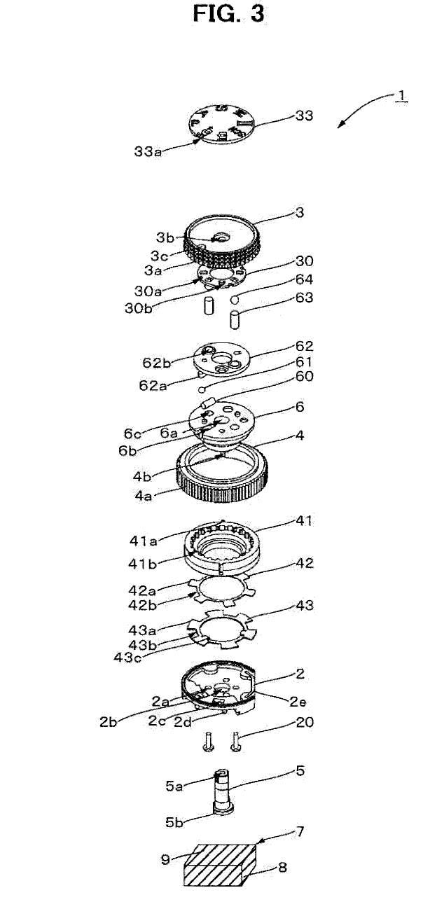

Next, an example of the respective members constituting the dial switch according to an embodiment of the present disclosure will be described. FIG. 3 shows an exploded view of the members of the configuration example of the dial switch according to an embodiment of the present disclosure. FIG. 4 shows a cross-sectional view of the dial switch according to an embodiment of the present disclosure. In addition, a cross-section shown in FIG. 4 is not a cross-section obtained by linearly cutting the dial switch 1 but a cross-section taken along line A-A illustrated in FIG. 2. Accordingly, in FIG. 4, both of a spring B60 extending in a direction parallel to the dial B4 and a spring A63 extending in a direction perpendicular to the dial A3 are shown. Further, in FIG. 4, hatching representing cross-sections of members other than a shaft A5 and a shaft B6 will be omitted for the purpose of convenience.

The dial switch 1 has the base plate 2, the dial A3, the dial B4, the shaft A5, the shaft B6, and a sensor unit 7. In FIG. 3, the respective members are shown in sequence of the dial A3, the shaft B6, the dial B4, the base plate 2, the shaft A5 and the sensor unit 7 from an upper side. In an embodiment of the present disclosure, a sensor A8, which is a mechanical sensor, and a sensor B9, which is a non-contact sensor, are used as the sensor unit 7. In addition, in the following description, the dial A3 side will be described as an upper side and the sensor unit 7 will be described as a lower side.

The dial B4 has a substantially annular shape as shown in FIG. 3. For example, a metal plate formed of aluminum or the like is used as the dial B4. Stripe shaped non-slip patterns are engraved in an outer circumferential surface 4a of the dial B4 through knurling. Meanwhile, a guide groove 4b extending vertically is formed in an inner circumferential surface of the dial B4.

A click plate B41 is fixed to a lower side of the dial B4. An outer circumference of the click plate B41 has a substantially circular shape, and an inner circumference thereof is formed in a stepped shape, a diameter of which is reduced as it goes downward. For example, a resin is used in the click plate B41. As the resin is used, the weight is reduced. A protrusion section 41a extending vertically is formed at the outer circumferential surface of the click plate B41 to correspond to a position of the guide groove 4b. When the dial B4 and the click plate B41 are fixed, as the guide groove 4b and the protrusion section 41a are fitted to each other, positioning is performed. Meanwhile, a plurality of click grooves 41b extending vertically are formed in the inner circumferential surface of the click plate B41.

A reflective plate 43 is attached from a lower side of the click plate B41 via a substantially annular shaped adhesive paper 42. The reflective plate 43 is a substantially annular flat plate. A material that can reflect light is used as the reflective plate 43. For example, a metal is used in the reflective plate 43. Stainless steel may be used as the reflective plate 43. Double sided tape may be used as the adhesive paper 42.

A plurality of reflective surfaces 43a further protruding radially in an outer circumferential direction are formed at the outer circumferential surface of the reflective plate 43. The respective reflective surfaces 43a have a substantially rectangular flat plate shape. In FIG. 3, the respective reflective surfaces 43a are formed at six places at the same interval. Meanwhile, a portion between the neighboring reflective surfaces 43a, i.e., a portion that does not protrude from the outer circumferential surface of the reflective plate 43 in the outer circumferential direction, is a non-reflective region 43b. In addition, a convex section 42a and a concave section 42b may be formed at the adhesive paper 42 to correspond to the reflective surface 43a and the non-reflective region 43b of the reflective plate 43.

Meanwhile, a plurality of positioning pieces 43c protruding in an inner circumferential direction are formed at the inner circumferential surface of the reflective plate 43. In FIG. 3, the positioning pieces 43c are formed at two places of the reflective plate 43. When the click plate B41 and the reflective plate 43 are adhered to each other, as an engaging groove and the positioning piece 43c are fitted to each other, in particular, positioning in the circumferential direction is performed.

The dial B4 to which the click plate B41 and the reflective plate 43 are adhered is placed on the base plate 2.

The base plate 2 has substantially a disc shape. For example, a resin is used in the base plate 2. A screw hole 2a penetrating vertically is formed in the base plate 2. In FIG. 3, the screw holes 2a are formed at two places of the base plate 2. An insertion hole 2b penetrating vertically is formed in a center of the substantially disc-shaped base plate 2.

Further, a light passage window 2c penetrating vertically is formed in the vicinity of the outer circumference of the base plate 2. A position at which the light passage window 2c is formed corresponds to positions of the reflective surface 43a and the non-reflective region 43b of the reflective plate 43 placed on the base plate 2. In FIG. 3, the light passage windows 2c are formed at two places of the base plate 2. According to rotation of the reflective plate 43, in an upper side of the two light passage windows 2c, the two light passage windows 2c are formed at an interval to be disposed in all of states of (1) the reflective surface 43a-the reflective surface 43a, (2) the reflective surface 43a-the non-reflective region 43b, (3) the non-reflective region 43b-the non-reflective region 43b, (4) the non-reflective region 43b-the reflective surface 43a.

A positioning protrusion 2d protruding downward from the base plate 2 is formed in the vicinity of the light passage window 2c under the base plate 2. In FIG. 3, the positioning protrusions 2d are formed at two places of the base plate 2. Further, a chord 2e is formed such that a position of the base plate 2 is cut out in the outer circumference showing a circular shape when the base plate 2 is seen in a plan view. When the dial switch 1 is attached to the imaging apparatus 100 (see FIG. 1), the chord 2e may meet a side between the top surface and the rear surface of the imaging apparatus 100. According to the above-mentioned positional relation, the outer circumferential surface 4a of the dial B4 protrudes to the rear surface side thereof more than the rear surface of the imaging apparatus 100, and thus the dial B4 is easily rotated.

The shaft B6 is placed on an inner circumferential region of the dial B4 and on the base plate 2 and the click plate B41. An outer circumferential surface of the shaft B6 has a columnar shape having a plurality of step shapes in which a diameter of a lower side is reduced. A shape of the outer circumferential surface of the shaft B6 is formed to correspond to the shape of the inner circumferential surface of the click plate B41. For example, a resin is used in the shaft B6.

A screw hole (not shown) is formed in a lower side of the shaft B6 at a position corresponding to the screw holes 2a of the base plate 2. Screw cutting is performed on the screw hole. A screw 20 passing through the screw hole 2a is inserted into the screw hole (not shown). The base plate 2 and the shaft B6 are fastened by the screw 20. In addition, the dial B4 and the click plate B41 are disposed between the base plate 2 and the shaft B6, and configured to be rotatable along an upper surface of the base plate 2 and the outer circumferential surface of the shaft B6.

An insertion hole 6a penetrating vertically is formed in the center of the shaft B6 to correspond to the insertion hole 2b of the base plate 2. Further, a spring accommodating concave section 6b formed in the shaft B6 in a groove shape in a central direction of the shaft B6 is formed from a position of the side between the upper surface and the outer circumferential surface thereof. Furthermore, a spring accommodating concave section 6c formed in a columnar shape in a downward direction is formed in the upper surface of the shaft B6. In FIG. 3, the spring accommodating concave sections 6c are formed at two places of the shaft B6. The two spring accommodating concave sections 6c are concentrically formed on the center of the shaft B6 as an axis.

A member formed as an elastic body and a member having a curved surface are accommodated in the spring accommodating concave section 6b of the shaft B6. The spring B60 and a ball B61 are examples of the elastic body and the member having the curved surface, respectively, that are accommodated therein. In addition, the spring B60 and the ball B61 may be, for example, integrally configured as long as they have curved surfaces at one ends thereof and a biasing force is applied to the curved surfaces.

For example, a metal is used in the spring B60 and the ball B61. The spring B60 is disposed nearer to the inner circumference side of the shaft B6 than the ball B61, and biases the ball B61 toward the outer circumference of the shaft B6 in a direction parallel to a rotation surface of the dial B4. The curved surface of the ball B61 is fitted into the click groove 41b of the inner circumferential surface of the click plate B41. When the dial B4 is rotated, the ball B61 is moved to the neighboring click groove 41b and the curved surface is fitted again. Here, rotation of the dial B4 is stopped, and an operational feeling (a click feeling) is obtained.

A holder 62 is placed on the shaft B6. The holder 62 has an annular shape. For example, a resin is used in the holder 62. A spring accommodating lid 62a is formed at a lower side of the holder 62 to protrude in a downward direction of the holder 62 to correspond to a position of the spring accommodating concave section 6b of the shaft B6. Further, a spring insertion hole 62b passing vertically through the holder 62 to correspond to the spring accommodating concave section 6c of the shaft B6 is formed in the holder 62.

The shaft B6 and the holder 62 are fitted into the spring accommodating concave section 6b such that the spring accommodating lid 62a is provided on the spring accommodating concave section 6b in a state in which the spring B60 and the ball B61 are accommodated. Further, a member formed as an elastic body and a member having a curved surface are accommodated in the spring insertion hole 62b and the spring accommodating concave section 6c. The spring A63 and a ball A64 are examples of the elastic body and the member having the curved surface, respectively, that are accommodated therein. In addition, the spring A63 and the ball A64 may be, for example, integrally formed with each other as long as they have curved surfaces formed at one ends thereof and a biasing force is applied to the curved surfaces.

For example, a metal is used in the spring A63 and the ball A64. The spring A63 is disposed nearer to (a lower side of) the shaft B6 than the ball A64, and biases the ball A64 to (an upper side of) the holder 62 in a direction perpendicular to the rotation surface of the dial B4. The spring A63 has a biasing force larger than that of the spring B60. As a magnitude of the biasing force of the spring A63 and the number of springs A63 are appropriately selected, firmness of the dial A3 upon rotation can be adjusted. This is also the same as in the spring B60.

The dial A3 has a disc shape. A diameter of the dial A3 is formed to be smaller than that of the dial B4. Accordingly, both of the dial A3 and the dial B4 are easily rotated. For example, a resin is used in the dial A3. For example, a non-slip pattern protruding in a rectangular conical shape is engraved in the outer circumferential surface 3a of the dial A3. An upper side surface of the dial A3 is engraved to a predetermined depth, leaving an outer circumferential section.

An insertion concave section (not shown) is formed in the center of the lower side of the dial A3 to correspond to positions of the insertion hole 2b and the insertion hole 6a. Meanwhile, an opening section 3b penetrating vertically is formed in the center of the upper side of the dial A3 to be concentric with an insertion concave section (not shown). A diameter of the opening section 3b is smaller than that of the insertion concave section (not shown). In addition, a periphery of the opening section 3b of the upper surface of the dial A3 is planarized. A guide convex section 3c protruding upward from the engraved upper surface is formed in the vicinity of the outer circumference of the dial A3.

A click plate A30 formed as an annular flat plate is mounted from a lower side of the dial A3. For example, a metal is used in the click plate A30. Stainless steel may be used in the click plate A30. As the stainless steel is used, durability is improved.

A cutout section 30a removed in the inner circumferential direction is formed in the outer circumferential surface of the click plate A30. For example, four cutout sections 30a are formed. A convex section (not shown) is formed at the lower surface of the dial A3 to correspond to the cutout section 30a. When the click plate A30 is mounted on the dial A3, as the cutout section 30a and the convex section (not shown) are fitted to each other, in particular, positioning in the circumferential direction is performed.

Further, a rectangular click hole 30b penetrating vertically is formed in the click plate A30. The click hole 30b is concentrically formed to correspond to the position of the ball A64. In an embodiment of the present disclosure, the eight click holes 30b are formed in the click plate A30 at the same interval. The click hole 30b has a size into which the curved surface of the ball A64 is fitted. In addition, the number of click holes 30b may be appropriately increased or reduced to correspond to the number of modes switched by the dial A3.

The curved surface of the ball A64 is fitted into the click hole 30b of the click plate A30. When the dial A3 is rotated, the ball A64 is moved to the neighboring click hole 30b and the curved surface is fitted again. Here, rotation of the dial A3 is stopped and an operational feeling (a click feeling) is obtained.

The dial A3 in which the click plate A30 is mounted overlaps the holder 62 (the shaft B6) to sandwich the spring A63 and the ball A64 between the dial A3 and the holder 62. In a state in which the base plate 2 to the dial A3 are overlapped, the shaft A5 is inserted from a lower side of the base plate 2.

The shaft A5 has a columnar shape. An outer diameter of the shaft A5 is formed to correspond to the insertion hole 2b and the insertion hole 6a. For example, a resin is used in the shaft A5. A fixing hole 5a is formed in an upper surface of the shaft A5. Screw cutting may be performed on the fixing hole 5a. Further, a flange section 5b protruding in the outer circumferential direction is formed at a lower surface of the shaft A5.

The shaft A5 passes through the insertion hole 2b and the insertion hole 6a to be inserted into the insertion concave section (not shown) of the dial A3. Here, a slight gap may be formed between the flange section 5b and a peripheral section of the insertion hole 2b of the base plate 2. Resistance upon rotation of the dial A3 (the shaft A5) can be reduced by the slight gap.

A fixing member such as a fixing screw or the like is introduced into the opening section 3b. The fixing member introduced from the opening section 3b is fixed into the fixing hole 5a. The shaft A5 and the dial A3 are fixed by the fixing member. Rotation of the dial A3 is transmitted to a mechanical sensor by the shaft A5 fixed to the dial A3.

As described above, as the fixing member is disposed in the vicinity of the top surface of the dial switch 1, the space of the dial B4 of the lower stage is not invaded. Further, as the fixing area by the fixing member has a shaft shape, a compact structure of the dial switch 1 can be realized. The shaft A5 and the dial A3 are configured to be rotatable along the inner circumferential surfaces of the base plate 2 and the shaft B6 and the upper surface of the shaft B6 formed by the peripheral section of the insertion hole 2b, the insertion hole 2b and the insertion hole 6a.

As described above, a plurality of functions such as respective click mechanisms of the dial A3 and the dial B4 (holding of the spring A63 and the spring B60), positioning of the rotary shaft (the shaft A5) of the dial A3 of the upper stage, sliding vertical support of the dial A3, rotational guiding (bearing) of the dial B4 of the lower stage, and covering of a gap between the upper and lower dials are integrated at the shaft B6. Accordingly, the number of parts of the dial switch 1 according to an embodiment of the present disclosure can be suppressed and a compact (slim) structure of the entire dial switch 1 can be realized.

In this way, the respective members from the base plate 2 to the dial A3 are integrally formed with each other, and each of the dial A3 and the dial B4 is configured to be freely rotatable about the same rotational center in the rotational direction throughout the entire circumference.

A decoration plate 33 is fixed to the upper surface of the dial A3. A guide groove section 33a cut from the outer circumferential section toward the inner circumference is formed at a lower surface of the decoration plate 33. The guide groove section 33a is formed at a position corresponding to the guide convex section 3c of the dial A3. When the decoration plate 33 is fixed to the upper surface of the dial A3, as the guide groove section 33a corresponds to the guide convex section 3c, in particular, positioning in the circumferential direction is performed.

The decoration plate 33 has a disc shape. Marks corresponding to the photographing modes or the like are attached to the top surface of the decoration plate 33 to correspond to the rotation position of the dial switch 1. In an embodiment of the present disclosure, eight kinds of marks are attached to correspond to the number of click holes 30b of the above-mentioned click plate A30 (or the number of switching modes). In addition, similar to the number of click holes 30b, the marks may be appropriately increased or reduced to correspond to the number of modes to be switched by the dial A3.

As described above, the sensor A8, which is a mechanical sensor, and the sensor B9, which is a non-contact sensor, are used as the sensor unit 7. In addition, the sensor A8 may be the non-contact sensor. Each of the sensor A8 and the sensor B9 is connected to a control unit (not shown) of the imaging apparatus 100 by a wiring (not shown). The control unit receives a signal obtained by detecting displacement of the dial switch 1, and controls the imaging apparatus 100. Further, in the dial switch 1 according to an embodiment of the present disclosure, rotation of the dial A3 of the upper stage is detected by the mechanical sensor, and rotation of the dial B4 of the lower stage is detected by the non-contact sensor. Furthermore, for the purpose of simplicity, in FIG. 3, the sensor unit 7 having the sensor A8, which is the mechanical sensor, and the sensor B9, which is the non-contact sensor, is shown as a box-shaped body.

The sensor A8 is a rotation position sensor having a shaft extending from a main body of the sensor A8 and configured to detect a position of the shaft when the shaft is rotated. The shaft A5 mechanically contacts the shaft of the sensor A8. The shaft has, for example, a D shape when seen from a plan view. A connecting concave section having a D shape when seen from a plan view (not shown) is formed at a lower side of the shaft A5. When the shaft A5 and the shaft of the sensor A8 are connected such that a cross-section of the shaft of the sensor A8 and the connecting concave section have the same shape, for example, the D shape, positioning in the circumferential direction can be performed.

In the mechanical sensor, an absolute position as well as relative displacement can be detected. However, in an embodiment of the present disclosure, since eight kinds of photographing modes are switched, the sensor A8 should be able to detect at least eight rotation positions of the shaft A5 (the dial A3). In addition, the minimum number of rotation positions of the shaft A5 (the dial A3) that should be detected is increased or reduced according to the number of switching modes.

Positioning holes (not shown) are formed in the vicinity of the sensor B9. The positioning holes (not shown) are formed at two places to correspond to the positioning protrusions 2d of the base plate 2. The positioning protrusions 2d are fitted into the positioning holes (not shown), and the sensor unit 7 is attached to the base plate 2.

For example, an optical sensor configured to detect reflected light is used in the sensor B9. The sensor B9 has a light emitting diode and a light receiving diode, which are assembled to each other. The sensors B9 are attached to two places to correspond to the light passage windows 2c. The sensor B9 radiates light to the reflective plate 43 through the light passage window 2c and detects the reflected light. From a viewpoint of intensity of the reflective light, the sensor B9 may be installed as close to the reflective plate 43 as possible.

As described above, as the reflective plate 43 is rotated, the reflective surface 43a or the non-reflective region 43b is disposed at an upper side of the light passage window 2c. Here, a signal when light is radiated and the reflected light from the reflective surface 43a is detected is High, and a signal when light is not reflected by the non-reflective region 43b and the reflected light is not detected is Low. Since the sensors B9 separately perform detection at two places, combinations of the detected results are as follows:

(1) High-High, (2) High-Low, (3) Low-Low, and (4) Low-High.

For example, as a position of the dial B4 is changed clockwise one by one, signals are detected in sequence of (1), (2), (3) and (4). In the conditions set as described above, when the signal is varied from (1) High-High to (2) High-Low, it can be detected that the dial B4 is displaced clockwise by one click. Meanwhile, when the signal is varied from (4) Low-High to (3) Low-Low, it can be detected that the dial B4 is displaced counterclockwise by one click.

In this way, the sensor B9 can detect the rotational direction and rotation position of the dial B4. This means that the dial switch 1 is not set to only ON/OFF, but for example, an increase or decrease in a parameter value can be set. In addition, in an embodiment of the present disclosure, the switch is configured such that the above-mentioned four combinations appear six times while the reflective plate 43 is rotated 360 degrees. In addition, the method of detecting the rotational direction and rotation position through non-contact is not limited to the light but may use magnetism or the like.

Next, in the respective dials (the dial A3 and the dial B4) of the upper and lower two stages of the dial switch 1, structures of a fixing section, a rotation detection unit and a click mechanism unit will be described in detail.

[Dial A3 of Upper Stage]

(Fixing Section)

The dial A3 and the shaft A5 of the upper stage are fixed by the shaft B6 and the base plate 2. In addition, the dial A3 and the shaft A5 are fixed by the fixing member.

(Rotation Detection Unit)

Rotation detection of the dial A3 of the upper stage is performed when a tip of the shaft A5 fastened to the dial A3 is connected to a shaft of a mechanical detection switch (the sensor A8) and the switch of the sensor A8 is rotated through the shaft of the sensor A8.

(Click Mechanism Unit)

The click mechanism unit of the dial A3 of the upper stage is constituted by the dial A3, the click plate A30, the ball A64, the spring A63, the shaft A5, and the shaft B6. As the spring A63 inserted into the shaft B6 pushes the ball A64 against the click plate A30 in a vertical (upward) direction, the operational feeling (the click feeling) is generated.

[Dial B4 of Lower Stage]

(Fixing Section)

The dial B4 and the click plate B41 of the lower stage are fixed by the shaft B6 and the base plate 2.

(Rotation Detection Unit)

The rotation detection of the dial B4 of the lower stage is performed by two reflective optical sensors (the sensors B9) and the reflective plate 43. In addition, the base plate 2 functions to position the sensor B9, and can more precisely fix the sensor B9 with respect to the reflective plate 43.

(Click Mechanism Unit)

The click mechanism unit of the dial B4 of the lower stage is constituted by the dial B4, the click plate B41, the ball B61, the spring B60, and the shaft B6. As the spring B60 inserted into the shaft B6 pushes the ball B61 in a direction parallel to the click plate B41, the operational feeling (the click feeling) is generated. In addition, as the holder 62 is placed above the shaft B6, the spring B60 and the ball B61 are disposed in the shaft B6.

As described above, in an embodiment of the present disclosure, the respective click springs are separately disposed in the vertical direction and the horizontal direction to share the shaft B6 and to be used in the click mechanism, and are also used to fix the respective dials, enabling reduction in structure of the dial switch 1. In addition, the number of clicks in the circumference can be freely selected by appropriately varying the respective click plates.

[Operation of Dial Switch]

According to the configuration of the dial switch in accordance with the embodiment of the above-mentioned present disclosure, the dial A3 of the upper stage and the dial B4 of the lower stage are respectively operated as follows.

(Dial A3)

The dial A3 is rotated by operation by a user. The dial A3 slides on the shaft B6. The shaft A5 fixed by the fixing member is rotated about a rotation center area of the dial A3. The shaft A5 passes through the base plate 2 and the shaft B6 and is pivotally guided by the base plate 2 and the shaft B6. The shaft A5 is in contact with a shaft extending from a main body of the sensor A8, which is the mechanical sensor. Rotation of the shaft A5 is detected by the sensor A8, and the rotation position and the rotational direction of the dial A3 are detected.

The dial A3 has the click plate A30. Meanwhile, the shaft B6 has the spring A63 and the ball A64 extending in a direction perpendicular to the rotation surface of the dial A3. The click hole 30b of the click plate A30 is opposite to the curved surface of the ball A64. As the dial A3 is rotated, the curved surface of the ball A64 is fitted into the click hole 30b, and the operational feeling (the click feeling) is generated.

(Dial B4)

The dial B4 is rotated by operation by the user. The click plate B41 is attached to the inner circumference of the dial B4, and the dial B4 and the click plate B41 are integrally rotated. The dial B4 and the click plate B41 slide on the base plate 2 and the outer circumference of the shaft B6. That is, the dial B4 and the click plate B41 are pivotally guided by the base plate 2 and the shaft B6. The reflective plate 43 is attached to the click plate B41. Meanwhile, the sensor B9, which is the non-contact sensor, is attached to the base plate 2 to be opposite to the reflective plate 43. Rotation of the reflective plate 43 (the click plate B41) is detected by the sensor B9, and the rotation position and the rotational direction of the dial B4 are detected.

The dial B4 (the click plate B41) has the click groove 41b formed in the inner circumferential section thereof. Meanwhile, the shaft B6 has the spring B60 and the ball B61 extending in a direction parallel to the rotation surface of the dial B4. The click groove 41b of the click plate B41 is opposite to the curved surface of the ball B61. As the dial B4 is rotated, the curved surface of the ball B61 is fitted into the click groove 41b, and the operational feeling (the click feeling) is generated.

As described above, in the dial switch according to an embodiment of the present disclosure, both of the dial A3 of the upper stage and the dial B4 of the lower stage are rotated throughout the entire circumference, the rotation position and the rotational direction of the respective dials can be detected, and the operational feeling (the click feeling) can be obtained upon rotation of the respective dials.

### 2. Variant

A variant of the dial switch according to an embodiment of the present disclosure will be described. As described above, the non-contact sensor configured to detect rotation of both of the dial A3 of the upper stage and the dial B4 of the lower stage, for example, the optical sensor, may be used. The dial A3 of the upper stage and the dial B4 of the lower stage may be moved in the axial direction (vertically), and may function separately upon operation. The dial A3 of the upper stage and the dial B4 of the lower stage may be moved in a direction perpendicular to the shaft (the dial A3 and the dial B4 are applied to a joystick), and may function as a cross key, a click (determination), or the like. A button may be further installed at a center of the dial A3 of the upper stage, and the button may be configured to function separately as a release or the like.

### Effect of Embodiment

Hereinabove, the dial switch according to an embodiment of the present disclosure has been described. The dial switch according to the embodiment of the present disclosure integrates two kinds of click mechanism units with an inner shaft (the shaft B6), and uses an optical detection mechanism in the rotation detection unit of at least one dial, enabling rotation of the two-stage dial in both directions throughout the entire circumference. Further, as the dial switch according to the embodiment of the present disclosure uses the optical detection mechanism, a portion of the mechanism essentially requiring rotation of the dial throughout the entire circumference can be removed, and the entire structure of the dial switch can be reduced in size (a slim type).

According to the dial switch of the embodiment of the present disclosure, the structure thereof can be simplified and reduced in size (the slim type), and the structure in which the two-stage dial is rotated in both directions throughout the entire circumference can be realized. Further, according to the dial switch of the embodiment of the present disclosure, the structure in which the dial of the lower stage having the click mechanism installed therein is rotatable throughout the entire circumference can be realized without selection of the structure in which the dial of the lower stage is not rotated throughout the entire circumference while the click mechanism is separately installed at the outside of the dial switch.

Further, according to the dial switch of the embodiment of the present disclosure, the structure of the small and simple dial switch in which the detection sensor of the upper stage removes necessity of an internal wiring and the shaft of the upper stage passing through the dial of the lower stage has a simple and compact structure can be realized without invasion of the rotation detection unit of the dial of the upper stage into a region of the dial of the lower stage. Further, according to the dial switch of the embodiment of the present disclosure, even in an installation structure of the dial, the structure in which the dial of the lower stage is rotated throughout the entire circumference is provided, and an increase in size of the structure is prevented with no interference among the rotation detection mechanism, the wiring and the fixing member of the dial of the lower stage.

In the dial switch according to the embodiment of the present disclosure, as the two-stage dial can be rotated in both directions throughout the entire circumference, camera functions can continue to be developed. Further, a rear surface dial, which is hardly mounted due to an increase in size and complexity of a mechanism, can be mounted on a compact camera by the dial switch according to the embodiment of the present disclosure. Further, in the dial switch according to the embodiment of the present disclosure, a structure in which two dials of a mode dial and a control dial are integrated in function and space can be mounted in the top surface warship section of the compact camera.

The dial switch according to the embodiment of the present disclosure can be applied to various electronic instruments such as an imaging apparatus, for example, a camera, a video camera, or the like. The dial switch can also be variously applied to various kinds of cameras such as a film type as well as a digital type, and further, from a high-end one eye camera to a compact camera.

Additionally, the present technology may also be configured as below.

(1) A dial switch including:

a first dial freely rotatable in a rotational direction throughout an entire circumference of the first dial;

a second dial freely rotatable about the same rotational center as the first dial in the rotational direction throughout the entire circumference; and

a non-contact sensor that detects a rotation position and a rotational direction of at least one of the first dial and the second dial.

(2) The dial switch according to (1), wherein the second dial is disposed under the first dial, and the non-contact sensor detects the rotation position and the rotational direction of the second dial.
(3) The dial switch according to any one of (1) and (2), further including:

a first shaft that transmits rotation of the first dial; and

a mechanical sensor that comes in contact with the first shaft,

wherein the mechanical sensor detects the rotation position and the rotational direction of the first dial.

(4) The dial switch according to any one of (1) to (3), further including:

a base plate; and

a second shaft fixed to the base plate,

wherein the second dial is rotated about the second shaft, and

wherein the non-contact sensor detects rotation of a member rotated by the second dial.

(5) The dial switch according to (4), wherein the non-contact sensor is fixed to the base plate.
(6) The dial switch according to any one of (1) and (2), further including:

a first shaft that transmits rotation of the first dial;

a mechanical sensor that comes in contact with the first shaft;

a base plate; and

a second shaft fixed to the base plate,

wherein the freely rotatable first shaft passes through a center of the second shaft,

wherein the mechanical sensor detects the rotation position and the rotational direction of the first dial,

wherein the second dial is rotated about the second shaft, and

wherein the non-contact sensor detects rotation of a member rotated by the second dial.

(7) The dial switch according to (4),

wherein the non-contact sensor is an optical sensor, and

wherein the rotating member is a reflective plate.

(8) The dial switch according to (4),

wherein the second shaft includes a first elastic body, a first curved surface, a second elastic body, and a second curved surface,

wherein the first elastic body biases the first curved surface in a direction perpendicular to a rotation surface;

wherein the second elastic body biases the second curved surface in a direction parallel to the rotation surface;

wherein the first curved surface generates an operational feeling by rotation of the first dial, and

wherein the second curved surface generates an operational feeling by rotation of the second dial.

(9) The dial switch according to any one of (1) to (8),

wherein the first dial is a mode switching dial, and

wherein the second dial is a parameter change dial.

The embodiments of the present disclosure have been described specifically. However, embodiments of the present disclosure are not limited to the above-described embodiment, but may be modified in various ways based on the technical sprit and essence of the present disclosure. For example, the configurations, the methods, the processes, the shapes, the materials, the numerical values, and the like mentioned in the above-described embodiments are merely examples. Different configurations, methods, processes, shapes, materials, numerical values, and the like may be used, as necessary.

Further, configuration, methods, processes, shapes, materials, numerical values and the like in the above-described embodiments may be combined insofar as they are not departing from the spirit of the present disclosure.

It should be understood by those skilled in the art that various modifications, combinations, sub-combinations and alterations may occur depending on design requirements and other factors insofar as they are within the scope of the appended claims or the equivalents thereof.

The present disclosure contains subject matter related to that disclosed in Japanese Priority Patent Application JP 2012-197614 filed in the Japan Patent Office on Sep. 7, 2012, the entire content of which is hereby incorporated by reference.

What is claimed is:

1. A dial switch comprising:
a first dial freely rotatable in a rotational direction throughout an entire circumference of the first dial;
a second dial freely rotatable about the same rotational center as the first dial in the rotational direction throughout the entire circumference; and
a non-contact sensor that detects a rotation position and a rotational direction of at least one of the first dial and the second dial.

2. The dial switch according to claim 1, wherein the second dial is disposed under the first dial, and the non-contact sensor detects the rotation position and the rotational direction of the second dial.

3. The dial switch according to claim 1, further comprising:
a first shaft that transmits rotation of the first dial; and
a mechanical sensor that comes in contact with the first shaft,
wherein the mechanical sensor detects the rotation position and the rotational direction of the first dial.

4. The dial switch according to claim 1, further comprising:
a base plate; and
a second shaft fixed to the base plate,
wherein the second dial is rotated about the second shaft, and
wherein the non-contact sensor detects rotation of a member rotated by the second dial.

5. The dial switch according to claim 4, wherein the non-contact sensor is fixed to the base plate.

6. The dial switch according to claim 1, further comprising:
a first shaft that transmits rotation of the first dial;
a mechanical sensor that comes in contact with the first shaft;
a base plate; and
a second shaft fixed to the base plate,
wherein the freely rotatable first shaft passes through a center of the second shaft,
wherein the mechanical sensor detects the rotation position and the rotational direction of the first dial,
wherein the second dial is rotated about the second shaft, and
wherein the non-contact sensor detects rotation of a member rotated by the second dial.

7. The dial switch according to claim 4,
wherein the non-contact sensor is an optical sensor, and
wherein the rotating member is a reflective plate.

8. The dial switch according to claim 4,
wherein the second shaft includes a first elastic body, a first curved surface, a second elastic body, and a second curved surface,
wherein the first elastic body biases the first curved surface in a direction perpendicular to a rotation surface;
wherein the second elastic body biases the second curved surface in a direction parallel to the rotation surface;
wherein the first curved surface generates an operational feeling by rotation of the first dial, and
wherein the second curved surface generates an operational feeling by rotation of the second dial.

9. The dial switch according to claim 1,
wherein the first dial is a mode switching dial, and
wherein the second dial is a parameter change dial.
